(19) United States
(12) Patent Application Publication
(10) Pub. No.: US 2009/0204878 A1
(43) Pub. Date: Aug. 13, 2009

(54) Digital File Marked By a Series of Marks the Concatenation of Which Forms a Message and Method for Extracting a Mark from Such a Digital File

(75) Inventor: Stephane Madrange, Saint-Germain en Laye (FR)

Correspondence Address: OLIFF & BERRIDGE, PLC, P.O. BOX 320850, ALEXANDRIA, VA, 22320-4850, US

(73) Assignee: ADENTIS, LA GARENNE COLOMBES (FR)

(21) Appl. No.: 12/223,082

(22) PCT Filed: Feb. 12, 2007
(86) PCT No.: PCT/FR2007/050776

§ 371 Date: Oct. 22, 2008

(30) Foreign Application Priority Data
Feb. 13, 2006 (FR) 0601250

(51) Int. Cl. G06F 17/30; H03M 13/09; G06F 11/10

(52) U.S. Cl. 714/807; 707/1; 707/104.1; 707/E17.009; 714/E11.032

(57) ABSTRACT

The marked digital file (10) comprises a plurality of portions, some of which (12) are marked with a mark (14) of a string of marks so as to form a string of marked portions (12). Concatenating the marks (14) of the string forms a message. Each mark (14) contains an identifier (I, I0 to I5, J0 to J2) of the mark (14) defined by a numerical value, this value varying from one mark (14) to another as a function of the order of the mark (14) in the marked string. The string of marked portions (12) includes sub-strings, each of at least two marked portions (12) such that all of the portions (12), of a given sub-string are marked by the same mark (14).

The present invention relates to a digital file marked by a string of marks which, when concatenated, form a message, and it also relates to a method of extracting a mark from a marked digital file.

In the state of the art, and in particular from WO 00/65840, a marked digital file is known of the type that comprises a plurality of portions, some of which are marked by a mark forming part of a string of marks so as to form a string of marked portions, the marks of the string forming a message when they are concatenated.

In the description below, the term “mark” is used to designate a set of bits inserted in a portion of a digital file and suitable for being extracted by a mark-extractor program capable of interpreting such marks.

Each bit of a mark is usually associated with a digital magnitude, and it corresponds to a variation in said digital magnitude.

Thus, one bit of a mark can be determined by analyzing the associated digital magnitude, the bit having the value 1 if the digital magnitude is greater than a predetermined value, and having the value 0 if the digital magnitude is less than the predetermined value.

For example, if the digital file portion is an image, then each bit of the mark may correspond to increasing or decreasing the brightness of one of the red, green, or blue components of a zone of the image, such as a pixel or a set of pixels.

When implementing steganography, each mark is hidden in the file, so that it is not possible to know that the mark exists without subjecting the file to deep analysis, in particular with the help of a mark-extractor program. Indeed, the variations in the digital magnitudes that correspond to the bits of the mark are generally not perceptible. Nevertheless, in some circumstances, it may be preferable for a mark to be visible.

It should be observed that the extractor program is also capable of concatenating the extracted mark so as to reconstitute the message and extract therefrom the information it contains.

By way of example, the message formed by the concatenated mark can be applied to combating illegal copying of the marked digital file. For this purpose, the message may comprise, for example, information identifying the author, the proprietor, and/or the destination of a particular marked digital file.

In a variant, the message may comprise a description of the digital file, or indeed it may be used for audience tracking.

When the digital file passes via a network, e.g. using an open systems interconnection (OSI) model or using an Internet protocol (IP), or when a digital file is broadcast, e.g. by radio; the digital file is generally transmitted in the form of packets, these packets subsequently being concatenated so as to reconstitute the digital file.

It can sometimes happen that certain packets are transmitted with errors that can modify the file as reconstituted compared with the original file, often without harm.

Nevertheless, when errors affect the marks, the message can be modified or can become unreadable. Thus, a message made up of marks that have been modified could, for example, no longer enable the author or the proprietor of the file to be identified, and thus might no longer be used in combating illegal copying, or more generally, could no longer be used in the application for which it is intended.

In order to remedy that drawback, each mark of the message is conventionally encoded using an error-correcting code such as a BCH code (acronym based on the names of the creators of this code: Bose, Chaudhuri, Hocquenghem).

It is known that such a code makes it possible, on decoding, to locate any erroneous bits in the transmitted mark. It should be observed that since bits are expressed in binary, locating an erroneous bit is sufficient for enabling it to be corrected, by changing its value.

Nevertheless, any particular error-correcting code is capable of correcting only some predefined number of bits that depends on the complexity of the particular error-correcting code. If the message has some number of errors greater than the predefined number of bits, then the error-correcting code can no longer reconstitute the original mark.

A particular object of the invention is to remedy that drawback by providing a digital file that makes it possible to limit the effects of possible errors in transmission on the message contained therein, and to do this regardless of the format or the purpose of the message, and regardless of the means involved in transmitting the message.

To this end, the invention provides a digital file of the above-specified type, characterized in that:
each mark contains an identifier of the mark, the identifier being defined by a digital value that varies from one mark to another as a function of the order of the mark in the string of marks; and
the string of marked portions includes sub-strings, each of at least two marked portions, such that all of the portions of a given sub-string are marked by the same mark.

Each mark is repeated at least once, and since each mark includes an identifier, it is possible, ignoring possible transmission errors, to identify all identical marks contained in the digital file.

Each bit of the repeated mark is likewise repeated. Below, the bits of identical marks that correspond to a given bit in the repeated original marks are referred to as a “given bit of identical marks”.

These given bits of identical marks ought to be identical, ignoring possible transmission errors.

Each of these given bits of identical marks corresponds to a variation in the same associated magnitude, as described above. It is then possible to accumulate all of the variations corresponding to the given bits of all of the identical marks, so as to obtain for each set of given bits an overall variation in the magnitude associated with the bit.

Since each overall variation is obtained by accumulating a plurality of variations that ought to be identical, it is less likely to be erroneous than a single variation corresponding to one bit in a single mark. Accumulation serves to attenuate the effects of error on one bit in one mark in comparison with a majority of given bits that are not erroneous in identical marks.

It should also be observed that the greater number of marked portions of the same mark that are contained in a sub-string, the greater the number of identical marks there are to be accumulated, and thus the more reliable the error correction.

It is then possible to deduce from each global variation as obtained in this way the corresponding bit of the extracted mark, with the risk of this bit being erroneous itself being reduced by means of the invention.

A mark extracted from a digital file of the invention thus includes fewer errors than a mark extracted from a conventional digital file.

As a result, since the potential number of errors is reduced, the risk of the number of errors exceeding the predefined number of bits that can be corrected by an error-correcting code is itself reduced. This therefore reduces the risk of the error-correcting code being incapable of reconstituting the original mark.

Finally, it should be observed that the invention makes it possible to correct a larger number of errors, thus making it possible to some extent to combat illegal copying methods that consist in adding errors in order to make the marks in a file unreadable.

Optionally, the identifier of the mark of the first sub-string of marked portions is defined by a predetermined numerical value, referred to as the start value, and the identifier of each other mark is defined by a numerical value higher than the values defining the identifiers of the marks that precede it.

Thus, the digital file may contain a plurality of series of marks, with the marks in each string being concatenated to form a different message.

When the extractor program extracts a mark having its identifier defined by a value that is higher than the value defining the identifiers of marks it has already extracted, it deduces therefrom that the mark forms part of the same string of marks as the previously-extracted marks.

In contrast when the extractor program extracts a mark having its identifier defined by the start value, it deduces that this mark forms part of a new marked string.

Preferably, each sub-string has the same number of portions.

Thus, in the light of the extracted sub-strings, the extractor program can determine how many portions are included in each sub-string. The extractor program thus expects to find each mark as many times as there are portions in each sub-string.

If an error relates to the identifier of a mark extracted from a marked portion, the extractor program can correct this error by observing the position of this portion in the sub-string of marked portions. This serves in particular to avoid the risk of the extractor program considering that an erroneous identifier is the identifier of a new mark.

A digital file of the invention may also include one or more of the following characteristics:
the digital file includes at least one portion that does not contain a mark, referred to as a non-marked portion, the marked portions being placed randomly relative to the non-marked portions;
each identifier is identified by a digital value expressed in bits numbered using Gray code, and it includes a parity bit;
each mark includes at least one sub-mark, each sub-mark being contained by a given portion and including the identifier associated with the mark and at least one data set;
the digital file is a video file, each portion of the file being an image, an image zone, or a set of images;
each mark of an image has three sub-marks incorporated respectively in the red, green, and blue components of the image; and
the digital file is marked by at least two distinct strings of marks which, on being concatenated, form a message, the messages corresponding to distinct strings together forming a message string in which the payloads are associated so as to form a single general payload, each message of the string of messages further including an item of information relating to the number of marked portions in another marked string which, on being concatenated, forms another message of the message string.

Also preferably, the message formed by the concatenated marks contain at least one item of information selected from: information relating to the number of marked portions of the message; information relating to the number of marked portions of another message contained in the digital file and adding to the message; information relating to the number of marked portions of another message contained in the digital file; information relating to the purpose of the message; information relating to the presence of other items of information in the message; information relating to the length of the message in bits; information relating to the payload of the message; information relating to authenticating the message; and information relating to a cyclic redundancy check.

It should be observed that a message formatted to include the above-defined information can be adapted to any application (combating illegal copying of the marked digital file, describing the digital file, audience tracking, or two or more of these applications simultaneously).

In addition, such a message can also be adapted to any technique for transmitting the digital file, the number of portions marked by sub-strings of marked portions depending in particular on the quality of the transmission technique, with this number being greater when the quality of transmission is low.

Finally, it should be observed that the invention can be applied to any digital file that is liable to be transmitted in the form of packets, the format of the message being independent of the digital file.

The invention also provides a method of extracting a mark from a marked digital file as defined above, each bit of the mark corresponding to a variation of a magnitude associated with the bit, the method being characterized in that it comprises:
a step of calculating global variations, during which, for each corresponding bit in the marks of a given sub-string, the magnitude corresponding to said bit is subjected to positive or negative variation depending on whether the bit is equal respectively to 1 or to 0, these variations accumulating with one another so as to form an overall variation; and
a step of determining the extracted mark, during which each calculated overall variation is associated with a corresponding bit equal to 1 if the overall variation is positive and equal to 0 if the overall variation is negative, the set of these bits forming the extracted mark.

Preferably, the extraction method further includes a step during which any residual errors of the mark are corrected with the help of an error-correcting code.

The invention can be better understood on reading the following description given purely by way of example and made with reference to the accompanying drawings, in which:

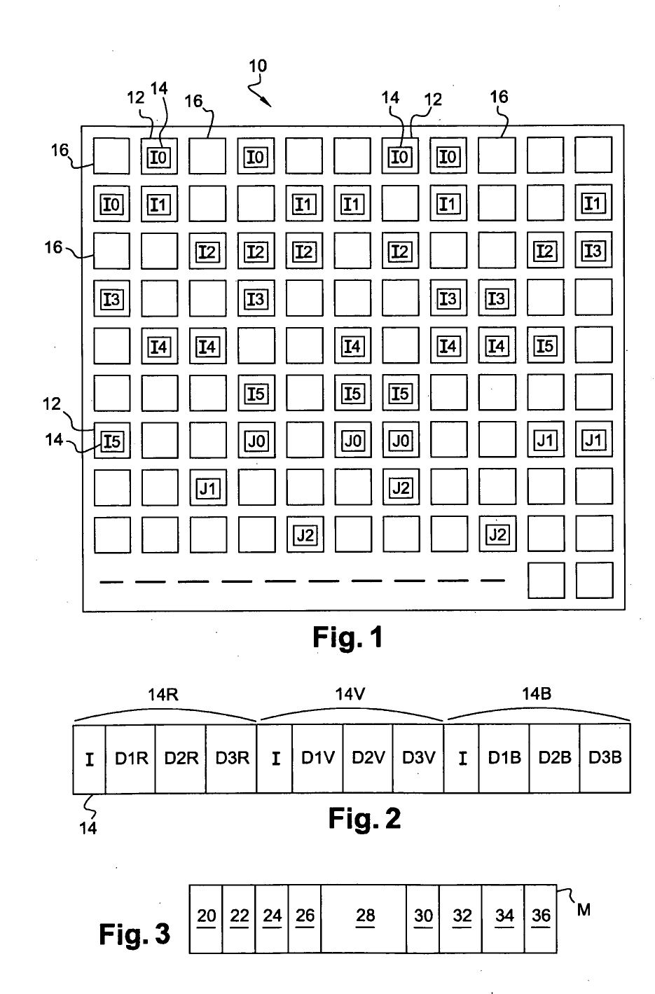

FIG. 1 shows a marked digital file of the invention;

FIG. 2 shows the structure of a mark of a marked portion of the FIG. 1 digital file; and

FIG. 3 shows the structure of a message obtained by concatenating the marks of the marked portions of the FIG. 1 digital file.

FIG. 1 shows a digital file constituting an embodiment of the invention. The digital file is given overall reference 10.

The digital file 10 comprises a plurality of portions, some of which, referred to as marked portions 12, are each marked with a mark 14 from a string of marks that, when concatenated, form a message. These marked portions 12 then form a string of marked portions.

The digital file also includes non-marked portions 16 placed amongst the marked portions 12. Preferably, the portions of the file 10 that are to receive a mark of the string of marks are selected randomly. Thus, the marked portions 12 are placed in random manner relative to the non-marked portions 16.

In the example shown, the digital file 10 is a video file. Each portion 12, 16 of the video file is then a video image. In a variant, each portion 12, 16 could be a zone of a video image, such as a pixel or a set of pixels, or it could be a set of video images.

In a variant, the digital file 10 could be a text file, each portion of the text file then being a page of text, or more generally the digital file 10 could be any digital file that can be subdivided into a plurality of portions.

In the example described, the digital file 10 has two strings of marks in which each mark 14 is inserted in a respective marked image 12. Naturally, a digital file of the invention could have as many strings of marks as necessary.

FIG. 2 shows greater detail of a mark 14 of a marked portion 12 of the digital file 10.

It should be observed that each mark 14 of the digital file 10, e.g. coded on 276 bits, is of structure identical to the structure of the other marks 14. Only the content of each mark 14 differs from one file to another.

In the example described, each mark 14 comprises three sub-marks 14R, 14G, and 14B each encoded on 92 bits, and respectively incorporated in the red, green, and blue components of the image 12 including the mark 14.

Each mark 14 contains an identifier I defined by a numerical value that varies from one mark 14 to another as a function of the order of the marks 14 in the string of marks. The identifier I serves in particular to inform a conventional mark-extractor program about the presence of a mark in the marked portion and about the position of the mark within the string of marks.

The identifier I of the first mark 14 in a string of marks is preferably defined by a predetermined numerical value, referred to as a start value. Generally, the start value is zero. The identifier I of each other mark 14 is defined by a numerical value that is greater than that defining the identifiers I of the mark 14 that precede it in the string of marks. Thus, when the mark-extractor program encounters an identifier I of value zero, it deduces therefrom that this is the identifier I of the first mark of a new string of marks.

Each sub-mark 14R, 14G, and 14B preferably contains the identifier I of the mark 14. Thus, if the identifier I included in a sub-mark contains an error, it is generally possible to deduce from the other two sub-marks what was the original non-erroneous identifier.

Preferably, each identifier I is defined by a digital value expressed in bits numbered using Gray code. It is known that using a Gray code when numbering elements in a string helps to detect any errors in the numbering. Each identifier I also includes a parity bit, that also serves to detect any errors in conventional manner.

Each sub-mark 14R, 14G, 14B contains three data sets designated respectively by the references D1R, D2R, & D3R; D1G, D2G, & D2G; and D1B, D2B, & D3B. Concatenating these data sets forms the payload of the mark 14, i.e. the data that is useful for rebuilding the message.

In FIG. 1, references I0, I1, I2, I3, I4, & I5, and respectively J0, J1, & J2 designate the identifiers of the marks 14 respectively in the first and second strings of marks inserted in the digital file 10. It should be observed that the identifiers designated by the references I0 and J0 are the identifiers of the first marks 14 in each of the strings of marks.

In order to limit the effects of any transmission errors on the marks, the strings of marked portions 12 include sub-strings of marked portions 12 such that all of the portions 12 of a given sub-string are marked with the same mark 14. The portions 12 marked with a given mark 14 thus contain the same identifier, as can be seen in FIG. 1.

Preferably, each sub-string of marked portions has the same number of portions 12. In the example described, each sub-string of portions marked by a mark 14 of the first or the second string of marks respectively comprises five or three portions 12 respectively. Since each mark 14 is repeated at least three times, it is generally possible to correct any errors that might be contained in the marks 14.

It is known that each of the same bits in the identical marks 14 correspond to variation of the same associated magnitude. It is thus possible to accumulate all of the variations corresponding to a given bit in all of the identical marks 14 so as to obtain, for each set of the same given bit, an overall variation in the magnitude associated with that bit.

Since each overall variation is obtained by accumulating a plurality of variations that are supposed all to be identical, it is less likely to be erroneous than a single variation corresponding to a single bit of a single mark. It is therefore possible to deduce from each overall variation as obtained in this way the corresponding bit of the original mark, with a reduced risk of this bit being erroneous.

Furthermore, by comparing the identifiers I of all of the marks in the series of portions, the extractor program can determine the number of portions making up each sub-string. Thus, if an error applies to the identifier I of a mark 14 extracted from a marked portion 12, the extractor program can correct this error and thus avoid running the risk of considering an erroneous identifier I as being the identifier I of some other mark.

Thus, by means of the invention, it is possible to implement a mark extraction method that makes it possible to correct for possible transmission errors.

The method comprises a step of calculating global variations, during which, for each particular bit in the mark of a given sub-string, positive or negative variation of the magnitude corresponding to said bit is applied depending on whether the bit is itself respectively 1 or 0. These variations thus accumulate between one another so as to form an overall variation for each particular bit.

Thereafter, the method comprises a step of determining the mark that has been extracted, during which a corresponding bit is associated with each calculated overall variation, the corresponding bit having the value 1 if the overall variation is positive and 0 if the overall variation is negative. The set of these bits makes up the extracted mark, with any errors contained in the original mark being for the most part corrected.

The extraction method preferably also comprises a step during which any residual errors in the mark are corrected with the help of an error-correcting code, in known manner.

Since the number of potential errors is small, there is a reduced risk of the number of errors being greater than the predefined number of bits that a particular error-correcting code can correct. This therefore reduces that the risk of the error-correcting being incapable of reconstituting the original mark.

The extraction method of the invention thus improves mark reconstitution after transmission.

It should be observed that since the marked portions 12 are located randomly relative to the non-marked portions 16, two digital files having similar contents generally do not have marks in the same sub-portions.

This reduces the risk of the marks in a file being damaged by collusion attacks, which constitute common methods of fabricating illegal copies of a file.

It is recalled that a collusion attack consists in averaging the magnitudes corresponding to the bits of the marks in identical marked portions from at least two files of similar contents, so as to obtain a file of similar content in which the marks have been modified, made illegible, or eliminated.

Thus, an extractor program can no longer reconstitute the message. This therefore produces a file that is not marked, i.e. that does not contain a message providing information concerning the author, the proprietor, and/or the destination of the file.

Since the marked portions 12 are located randomly relative to the non-marked portions 16 it is unlikely that two identical marked portions in two files with similar content will contain a similar mark, thus making collusion attacks difficult.

A collusion attack nevertheless remains possible with the help of a large number of files of similar contents, since having a large number of such files available increases the probability that two identical marked portions from two files taken from those that are available will contain a similar mark. Nevertheless, under such circumstances, collusion will generate noise, thereby significantly reducing the quality of the non-marked file that is obtained by the collusion attack.

Furthermore, since each mark is inserted in a plurality of marked portions 12, it is necessary to damage all of the identical marks contained by the file, thereby further complicating any possible attack by collusion.

Thus, by randomly choosing the portions of the file 10 that are to receive a mark 14, it is generally possible to find marks that are undamaged in order to reconstitute the message of a digital file in spite of a collusion attack.

FIG. 3 shows a message M obtained by concatenating the marks of a string of marks contained in the digital file 10 of the invention.

Such a message M generally comprises the following information.

A first item of information 20 concerns the purpose of the message. This information is generally recorded on 8 bits and specified, for example, that the message M is for identifying the author or the proprietor of the digital file, or for describing the digital file 10, or for audience tracking.

A second item of information 22, generally coded on 20 bits, indicates the number of portions 12 that are marked by a mark 14 in the string of marks that form the message M on being concatenated. This information makes it possible in particular to verify that the digital file 10 does indeed contain all of the marked portions 12.

When the digital file 10 contains a plurality of messages, a third item of information 24, generally coded on 20 bits, indicates the number of portions marked by a mark 14 in a string of marks that form another message when concatenated. Thus, the extractor program is warned about the number of marked portions in the other message, in order to detect any errors.

A fifth item of information 26, generally coded on 10 bits, gives the length as a number of bits of the useful content of the message.

This useful content of the message is a sixth item of information 28. It generally depends on the purpose of the message.

It should be observed that when this useful content is too long to be contained in a single message M, then it is necessary to spread it over a plurality of messages, together forming a message string.

Under such circumstances, each message in the message string includes a seventh item of information 30, generally coded on 20 bits, specifying the number of marked portions of the following message in the message string.

An eighth item of information 32 contains an electronic signature for authenticating the message.

A ninth item of information 36, generally coded on 6 bits, provides information concerning the presence or absence of other items of information contained in the message.

Finally, a last item of information 36, generally coded on 32 bits, provides a conventional type of cyclic redundancy check code that can be used for rejecting. messages that have too many errors.

Finally, it should be observed that the invention is not limited to the embodiment described above. Certain optional elements can be added to or removed from the digital file without thereby going beyond the ambit of the invention.

1. A marked digital file of the type comprising a plurality of portions in which some portions are marked by a mark of a string of marks so as to form a string of marked portions, the marks of the string forming a message (M) when they are concatenated, the file being wherein:
each mark contains an identifier of the mark, the identifier being defined by a digital value that varies from one mark to another as a function of the order of the mark in the string of marks; and
the string of marked portions includes sub-strings, each of at least two marked portions, such that all of the portions of a given sub-string are marked by the same mark.

2. A digital file according to claim 1, wherein the identifier of the mark of the first sub-string of marked portions is defined by a predetermined numerical value, referred to as the start value, and the identifier of each other mark is defined by a numerical value higher than the values defining the identifiers of the marks that precede it.

3. A digital file according to claim 1, wherein each sub-string has the same number of portions.

4. A digital file according to claim 1, wherein it includes at least one portion that does not contain a mark, referred to as a non-marked portion, the marked portions being placed randomly relative to the non-marked portions.

5. A digital file according to claim 1, wherein each mark includes at least two sub-marks contained by a given portion, each sub-mark including the identifier associated with the mark, and at least one data set.

6. A digital file according to claim 1, wherein it is a video file, each portion of the file being an image, an image zone, or a set of images.

7. A digital file according to claim 5, in which each mark of an image has three sub-marks incorporated respectively in the red, green, and blue components of the image.

8. A digital file according claim 1, wherein the message made up of by the concatenated marks contained an item of information concerning the payload of the message, and at least one item of information selected from:
information relating to the number of marked portions of the message;
information relating to the number of marked portions of another message contained in the digital file;
information relating to the purpose of the message;
information relating to the presence of other items of information in the message;
information relating to the length of the message in bits;
information relating to authenticating the message; and
information constituting a cyclic redundancy check.

9. A digital file according to claim 8, wherein it is marked by at least two distinct strings of marks which, on being concatenated, form a message, the messages corresponding to distinct strings together forming a message string in which the payloads are associated so as to form a single general payload, each message of the string of messages further including an item of information relating to the number of marked portions in another marked string which, on being concatenated, forms another message of the message string.

10. A method of extracting a mark from a marked digital file according to claim 1, each bit of the mark corresponding to a variation of a magnitude associated with the bit, the method being wherein it comprises:
a step of calculating global variations, during which, for each corresponding bit in the marks of a given sub-string, the magnitude corresponding to said bit is subjected to positive or negative variation depending on whether the bit is equal respectively to 1 or to 0, these variations accumulating with one another so as to form an overall variation; and
a step of determining the extracted mark, during which each calculated overall variation is associated with a corresponding bit equal to 1 if the overall variation is positive and equal to 0 if the overall variation is negative, the set of these bits forming the extracted mark.
